(19) United States
(12) Patent Application Publication
(10) Pub. No.: US 2014/0175345 A1
(43) Pub. Date: Jun. 26, 2014

(54) Photosensitive Resin Composition for Color Filter and Color Filter Using the Same

(71) Applicant: Cheil Industries Inc., Gumi-si (KR)

(72) Inventors: Nam-Gwang KIM, Uiwang-si (KR); Se-Young CHOI, Uiwang-si (KR); Kyung-Hee HYUNG, Uiwang-si (KR); Yu-Jin LEE, Uiwang-si (KR); Gyu-Seok HAN, Uiwang-si (KR)

(73) Assignee: Cheil Industries Inc., Gumi-si (KR)

(21) Appl. No.: 13/972,335

(22) Filed: Aug. 21, 2013

(30) Foreign Application Priority Data
Dec. 24, 2012 (KR) 10-2012-0152459

(51) Int. Cl. G03F 7/00

(52) U.S. Cl. CPC G03F 7/0007
USPC 252/586; 430/281.1

(57) ABSTRACT

Disclosed are a photosensitive resin composition for a color filter including (A) a colorant including green pigment and a color material having transmittance of about 0 to about 40% in a wavelength region of about 490 to about 500 nm, and transmittance of about 70 to about 100% in a wavelength region of about 520 to about 530 nm, (B) an acrylic-based binder resin, (C) a photopolymerization initiator, (D) a photopolymerizable monomer, and (E) a solvent, and a color filter using the same.

### CROSS-REFERENCE TO RELATED APPLICATION

This application claims priority to and the benefit of Korean Patent Application No. 10-2012-0152459 filed in the Korean Intellectual Property Office on Dec. 24, 2012, the entire disclosure of which is incorporated herein by reference.

### FIELD OF THE INVENTION

This disclosure relates to a photosensitive resin composition for a color filter and a color filter using the same.

### BACKGROUND OF THE INVENTION

Recently, as the use of large screen liquid crystal displays (LCD) has significantly increased, it has become increasingly important to improve the performance of the same. There is active research on increasing the process margin of a color filter for productivity, since the color filter is the most important factor in realizing colors among the many parts of a liquid crystal display. In addition, in order to increase color purity of a large screen liquid crystal display (LCD), a color filter can be manufactured using a photosensitive resin composition prepared by increasing concentration of a colorant. Accordingly, a photosensitive resin composition is required to have lowered development speed to increase productivity and yield in the manufacturing process and to have excellent sensitivity despite little exposure to light.

A photosensitive resin composition for a color filter can be used to manufacture a color filter through methods such as dyeing, electrophoretic deposition (EPD), printing, pigment dispersion, and the like, in which three or more colors are coated on a transparent substrate. Recently, the pigment dispersion method has been more actively adopted.

Particularly, a photosensitive resin composition for a color filter used in the pigment dispersion method can include an alkali soluble resin, a photopolymerization monomer, a photopolymerization initiator, an epoxy resin, a solvent, and other additives. Recently, high color reproducibility ratio and high luminescence characteristics as well as excellent pattern characteristics are required.

On the other hand, an image sensor is a part for photographing images in a portable phone camera or a DSC (digital still camera). It may be classified as a charge-coupled device (CCD) image sensor or a complementary metal oxide semiconductor (CMOS) image sensor depending upon the manufacturing process and the application method.

A recent color filter mounted in the color imaging device that is used in the charge-coupled device or the complementary metal oxide semiconductor has a pattern size of about 2 μm or less, which is 1/100th to 1/200th of the pattern size of a conventional color filter pattern for LCDs.

Accordingly, increased resolution and decreased pattern residues are important factors for determining the performance of a device.

In order to express the photographing image near to the real color, a photosensitive resin composition for a color filter is required to have a high color reproduction ratio.

### SUMMARY OF THE INVENTION

One embodiment of the present invention provides a photosensitive resin composition for a color filter that can have high selective transmittance and improved color reproducibility.

Another embodiment of the present invention provides a color filter manufactured using the photosensitive resin composition for a color filter.

One embodiment of the present invention provides a photosensitive resin composition for a color filter that includes (A) a colorant including green pigment and a color material having transmittance of about 0 to about 40% in a wavelength region of about 490 to about 500 nm, and transmittance of about 70 to about 100% in a wavelength region of about 520 to about 530 nm, (B) an acrylic-based binder resin, (C) a photopolymerization initiator, (D) a photopolymerizable monomer, and (E) a solvent.

The color material may have transmittance of about 80 to about 100% in a wavelength region of about 520 to about 530 nm. The color material may include C.I. solvent yellow 19, C.I. solvent yellow 21, C.I. solvent yellow 179, C.I. yellow pigment 150, C.I. yellow pigment 185, or a combination thereof.

The green pigment may include C.I. green pigment 7, C.I. green pigment 36, C.I. green pigment 58 or a combination thereof.

The colorant may include the color material and the green pigment in a weight ratio of about 20:1 to about 1:20.

The photosensitive resin composition for a color filter may include about 0.01 to about 60 wt % of the colorant (A), about 0.5 to about 20 wt % of the acrylic-based binder resin (B), about 0.1 to about 10 wt % of the photopolymerization initiator (C), about 0.5 to about 20 wt % of the photopolymerizable monomer (D), and a balance amount of the solvent (E).

Another embodiment of the present invention provides a color filter manufactured using the photosensitive resin composition for a color filter.

Other embodiments of the present invention are included in the following detailed description.

The photosensitive resin composition for a color filter can have high selective transmittance and may provide a color filter having excellent color reproducibility.

### BRIEF DESCRIPTION OF THE DRAWING

FIG. 1 is a graph showing transmittance according to a wavelength of colorants according to Example 1, Example 2, and Comparative Example 1.

### DETAILED DESCRIPTION

The present invention will be described more fully hereinafter in the following detailed description of the invention, in which some but not all embodiments of the invention are described. Indeed, this invention may be embodied in many different forms and should not be construed as limited to the embodiments set forth herein; rather, these embodiments are provided so that this disclosure will satisfy applicable legal requirements.

As used herein, when a specific definition is not otherwise provided, “(meth)acrylate” refers to both “acrylate” and “methacrylate”.

A photosensitive resin composition for a color filter according to one embodiment includes (A) a colorant including a green pigment and a color material having transmittance of about 0 to about 40% in a wavelength region of about 490 to about 500 nm, and transmittance of about 70 to about 100% in a wavelength region of about 520 to about 530 nm, such as a yellow color material described herein, (B) an acrylic-based binder resin, (C) a photopolymerization initiator, (D) a photopolymerizable monomer, and (E) a solvent.

(A) Colorant

The colorant may include a mixture of a green pigment and a color material having transmittance of about 0 to about 40% in a wavelength region of about 490 to about 500 nm, and transmittance of about 70 to about 100% in a wavelength region of about 520 to about 530 nm.

The color material may have transmittance of about 80 to about 100% in a wavelength region of about 520 to about 530 nm. The color material having the wavelength region and the transmittance within the above ranges can have excellent wavelength region selectivity and a high transmittance in a predetermined wavelength region, so the spectral characteristics can be enhanced. The photosensitive resin composition for a color filter including the color material may also exhibit high dispersion stability.

Examples of the color material may include C.I. solvent yellow 19, C.I. solvent yellow 21, C.I. solvent yellow 179, C.I. yellow pigment 150, C.I. yellow pigment 185, and the like, and combinations thereof, but is not limited thereto.

The colorant may include a green pigment as well as the color material. Examples of the green pigment may include without limitation C.I. green pigment 7, C.I. green pigment 36, C.I. green pigment 58, and the like, and combinations thereof, for example C.I. green pigment 58. When the green pigment is mixed with the yellow color material, the photosensitive resin composition for a color filter may transmit a green light in a high transmittance, so as to provide a color filter having excellent green color reproducibility.

The colorant may include the color material and the green pigment in a weight ratio of about 20:1 to about 1:20, for example about 10:1 to about 1:10. When mixed within the above weight ratio range, durability can be improved, and high luminance and excellent color characteristics may be accomplished.

The pigment may have a decreased primary particle diameter. Methods of decreasing the primary particle diameter of the pigment may include mixing a pigment with a water-soluble inorganic salt and a wetting agent and knead-pulverizing the same in a high pressure kneader to decrease the primary particle diameter to less than or about 70 nm; a acid pasting method of dissolving a pigment in acid such as sulfuric acid and adding the same into a poor solvent and depositing the same to decrease the primary particle diameter of pigment; and/or a method of dry-milling a pigment by a high-speed sand mil for a time sufficient to decrease the primary particle diameter of pigment, but is not limited thereto. In addition, a commercially available pigment can be used as long as the primary particle diameter is already reduced.

The pigment may have a primary particle diameter (D50) of about 30 to about 70 nm. When the pigment has a primary particle diameter within this range, heat resistance, chemical resistance, durability and the like may be improved after forming a pixel.

The pigment may be included in the photosensitive resin composition for a color filter as a dispersion. A pigment dispersion may include the pigment and solvent, a dispersing agent, a binder resin, and the like.

Examples of the solvent may include without limitation ethylene glycol acetate, ethyl cellosolve, propylene glycol methyl ether acetate, ethyl lactate, polyethylene glycol, cyclohexanone, propylene glycol methyl ether, and the like, and combinations thereof. In exemplary embodiments, propylene glycol methyl ether acetate may be used.

The dispersing agent helps to uniformly disperse the pigment and examples include without limitation non-ionic, anionic, and/or cationic dispersing agents. Specific examples of the dispersing agent may include without limitation polyalkylene glycol or esters thereof, polyoxy alkylenes, polyhydric alcohol ester alkylene oxide addition products, alcohol alkylene oxide addition products, sulfonate esters, sulfonate salts, carboxylate esters, carboxylate salts, alkyl amide alkylene oxide addition products, alkyl amines, and the like, and they may be used singularly or as a mixture of two or more.

The binder resin may include an acrylic-based resin including a carboxyl group and may improve pattern formation of pixels as well as stability of a pigment dispersion.

The pigment may have a primary particle diameter ranging from about 10 to about 70 nm. When the pigment has a primary particle diameter within this range, stability in a pigment dispersion and resolution of pixels may be excellent.

There is no particular limit to the secondary particle diameter of the pigment. In exemplary embodiments, the pigment may have a secondary particle diameter of less than or equal to about 200 nm, for example, from about 70 to about 100 nm, taking into account the resolution of pixels.

The photosensitive resin composition may include the colorant in an amount of about 0.01 to about 60 wt %, for example about 0.5 to about 50 wt %, based on the total amount (100 wt %) of the photosensitive resin composition for a color filter. In some embodiments, the photosensitive resin composition may include the colorant in an amount of about 0.01, 0.02, 0.03, 0.04, 0.05, 0.06, 0.07, 0.08, 0.09, 0.1, 0.2, 0.3, 0.4, 0.5, 0.6, 0.7, 0.8, 0.9, 1, 2, 3, 4, 5, 6, 7, 8, 9, 10, 11, 12, 13, 14, 15, 16, 17, 18, 19, 20, 21, 22, 23, 24, 25, 26, 27, 28, 29, 30, 31, 32, 33, 34, 35, 36, 37, 38, 39, 40, 41, 42, 43, 44, 45, 46, 47, 48, 49, 50, 51, 52, 53, 54, 55, 56, 55, 58, 59, or 60 wt %. Further, according to some embodiments of the present invention, the amount of the colorant can be in a range from about any of the foregoing amounts to about any other of the foregoing amounts.

When the colorant is used within in an amount within the above range, high solubility and excellent chemical resistance as well as high luminance and contrast ratio may be obtained.

(B) Acrylic-Based Binder Resin

The acrylic-based binder resin is a copolymer of a first ethylenic unsaturated monomer and a second ethylenic unsaturated monomer that is copolymerizable therewith, and includes at least one acrylic-based repeating unit.

The first ethylenic unsaturated monomer is an ethylenic unsaturated monomer including at least one carboxyl group. Examples of the monomer include without limitation acrylic acid, methacrylic acid, maleic acid, itaconic acid, fumaric acid, and the like, and combinations thereof.

The acrylic-based binder resin may include the first ethylenic unsaturated monomer in an amount ranging from about 5 to about 50 wt %, for example about 10 to about 40 wt %, based on the total amount (100 wt %) of the acrylic-based binder resin. In some embodiments, the acrylic-based binder resin may include the first ethylenic unsaturated monomer in an amount of about 5, 6, 7, 8, 9, 10, 11, 12, 13, 14, 15, 16, 17, 18, 19, 20, 21, 22, 23, 24, 25, 26, 27, 28, 29, 30, 31, 32, 33, 34, 35, 36, 37, 38, 39, 40, 41, 42, 43, 44, 45, 46, 47, 48, 49, or 50 wt %. Further, according to some embodiments of the present invention, the amount of the first ethylenic unsaturated monomer can be in a range from about any of the foregoing amounts to about any other of the foregoing amounts.

Examples of the second ethylenic unsaturated monomer may include without limitation aromatic vinyl compounds such as styrene, α-methylstyrene, vinyltoluene, vinylbenzylmethylether, and the like; unsaturated carboxylate ester compounds such as methyl(meth)acrylate, ethyl(meth)acrylate, butyl(meth)acrylate, 2-hydroxyethyl(meth)acrylate, 2-hydroxybutyl(meth)acrylate, benzyl(meth)acrylate, cyclohexyl(meth)acrylate, phenyl(meth)acrylate, and the like; unsaturated carboxylic acid amino alkyl ester compounds such as 2-aminoethyl(meth)acrylate, 2-dimethylaminoethyl(meth)acrylate, and the like; carboxylic acid vinyl ester compounds such as vinyl acetate, vinyl benzoate, and the like; unsaturated carboxylic acid glycidyl ester compounds such as glycidyl(meth)acrylate and the like; vinyl cyanide compounds such as (meth)acrylonitrile and the like; unsaturated amide compounds such as (meth)acrylamide and the like; and the like, and may be used singularly or as a mixture of two or more. Specific examples of the acrylic-based binder resin may include without limitation a methacrylic acid/benzylmethacrylate copolymer, a methacrylic acid/benzylmethacrylate/styrene copolymer, a methacrylic acid/benzyl methacrylate/2-hydroxyethylmethacrylate copolymer, a methacrylic acid/benzyl methacrylate/styrene/2-hydroxyethylmethacrylate copolymer, and the like. These may be used singularly or as a mixture of two or more.

The acrylic-based binder resin may have a weight average molecular weight ranging from about 3,000 to about 150,000, for example about 5,000 to about 50,000, and as another example about 20,000 to about 30,000. When the acrylic-based binder resin has a weight average molecular weight within the above range, the composition may have excellent close contacting (adhesive) property with a substrate, good physical and chemical properties, and appropriate viscosity.

The acrylic-based binder resin may have an acid value ranging from about 15 to about 60 mgKOH/g, for example about 20 to about 50 mgKOH/g. When the acrylic-based binder resin has an acid value within the above range, it can bring about excellent pixel resolution.

The photosensitive resin composition may include the acrylic-based binder resin in an amount ranging from about 0.5 to about 20 wt %, for example about 1 to about 15 wt %, based on the total amount (100 wt %) of the photosensitive resin composition for a color filter. In some embodiments, the photosensitive resin composition may include the acrylic-based binder resin in an amount of about 0.5, 0.6, 0.7, 0.8, 0.9, 1, 2, 3, 4, 5, 6, 7, 8, 9, 10, 11, 12, 13, 14, 15, 16, 17, 18, 19, or 20 wt %. Further, according to some embodiments of the present invention, the amount of the acrylic-based binder resin can be in a range from about any of the foregoing amounts to about any other of the foregoing amounts.

When the binder resin is included in the pigment dispersion for the stable dispersion of pigment, the amount of acrylic-based binder resin may be decreased by the amount used in the pigment dispersion.

When the acrylic-based binder resin is included in an amount within the above range, the composition may have an excellent developing property and improved cross-linking, and thus can provide excellent surface flatness when manufacturing a color filter.

(C) Photopolymerization Initiator

Examples of the photopolymerization initiator may include without limitation acetophenone-based compounds, benzophenone-based compounds, thioxanthone-based compounds, benzoin-based compounds, triazine-based compounds, oxime-based compounds, and the like, and combinations thereof.

Examples of the acetophenone-based compound may include without limitation 2,2′-diethoxyacetophenone, 2,2′-dibutoxyacetophenone, 2-hydroxy-2-methylpropiophenone, p-t-butyltrichloroacetophenone, p-t-butyldichloroacetophenone, 4-chloroacetophenone, 2,2′-dichloro-4-phenoxyacetophenone, 2-methyl-1-(4-(methylthio)phenyl)-2-(4-morpholinopropan)-1-one, 2-benzyl-2-(dimethylamino)-1-(4-(4-morpholinophenyl)-butan-1-one, and the like, and combinations thereof.

Examples of the benzophenone-based compound may include without limitation benzophenone, benzoyl benzoate, benzoyl methyl benzoate, 4-phenyl benzophenone, hydroxy benzophenone, acrylated benzophenone, 4,4′-bis(dimethyl amino)benzophenone, 4,4′-bis(diethylamino)benzophenone, 4,4′-dimethylaminobenzophenone, 4,4′-dichlorobenzophenone, 3,3′-dimethyl-2-methoxybenzophenone, and the like, and combinations thereof.

Examples of the thioxanthone-based compound may include without limitation thioxanthone, 2-methylthioxanthone, isopropyl thioxanthone, 2,4-diethyl thioxanthone, 2,4-diisopropyl thioxanthone, 2-chlorothioxanthone, and the like, and combinations thereof.

Examples of the benzoin-based compound may include without limitation benzoin, benzoin methyl ether, benzoin ethyl ether, benzoin isopropyl ether, benzoin isobutyl ether, benzyldimethylketal, and the like, and combinations thereof.

Examples of the triazine-based compound may include without limitation 2,4,6-trichloro-s-triazine, 2-phenyl 4,6-bis(trichloromethyl)-s-triazine, 2-(3′,4′-dimethoxystyryl)-4,6-bis(trichloromethyl)-s-triazine, 2-(4′-methoxynaphthyl)-4,6-bis(trichloromethyl)-s-triazine, 2-(p-methoxyphenyl)-4,6-bis(trichloromethyl)-s-triazine, 2-(p-tolyl)-4,6-bis(trichloro methyl)-s-triazine, 2-biphenyl 4,6-bis(trichloro methyl)-s-triazine, bis(trichloromethyl)-6-styryl-s-triazine, 2-(naphto1-yl)-4,6-bis(trichloromethyl)-s-triazine, 2-(4-methoxynaphto1-yl)-4,6-bis(trichloromethyl)-s-triazine, 2,4-trichloromethyl(piperonyl)-6-triazine, 2,4-trichloromethyl(4′-methoxystyryl)-6-triazine, and the like, and combinations thereof.

Examples of the oxime-based compound may include without limitation 1,2-octandione, 2-(o-benzoyloxime)-1-[4-(phenylthio)phenyl]-1,2-octandione, 1-(o-acetyloxime)-1-[9-ethyl-6-(2-methylbenzoyl)-9H-carbazol-3-yl]ethanone, and the like, and combinations thereof.

Other examples of the photopolymerization initiator may include without limitation carbazole-based compounds, diketone-based compounds, sulfonium borate-based compounds, diazo-based compounds, biimidazole-based compounds, and the like, and combinations thereof, in addition to and/or in combination with the aforementioned photopolymerization initiators.

The photosensitive resin composition may include the photopolymerization initiator in an amount ranging from about 0.1 to about 10 wt %, for example about 1 to about 5 wt %, based on the total amount (100 wt %) of the photosensitive resin composition for a color filter. In some embodiments, the photosensitive resin composition may include the photopolymerization initiator in an amount of about 0.1, 0.2, 0.3, 0.4, 0.5, 0.6, 0.7, 0.8, 0.9, 1, 2, 3, 4, 5, 6, 7, 8, 9, or 10 wt %. Further, according to some embodiments of the present invention, the amount of the photopolymerization initiator can be in a range from about any of the foregoing amounts to about any other of the foregoing amounts.

When the photopolymerization initiator is included in an amount within the above range, the photopolymerization can be sufficiently performed by exposure in the patterning process for a color filter, so that the sensitivity can be enhanced, the linearity of pattern can be enhanced, the solubility to the solvent and the storage stability can be enhanced, and non-reacted initiator may not remain after photopolymerization so as to prevent or minimize transmittance deterioration.

(D) Photopolymerizable Monomer

The photopolymerizable monomer may be a multi-functional monomer having two or more hydroxy groups. Examples of photopolymerizable monomer may include without limitation glycerol acrylate, dipentaerythritol hexaacrylate, ethylene glycol diacrylate, triethylene glycol diacrylate, 1,4-butanediol diacrylate, 1,6-hexanediol diacrylate, neopentylglycol diacrylate, pentaerythritol diacrylate, pentaerythritol triacrylate, dipentaerythritol triacrylate, dipentaerythritol acrylate, pentaerythritol hexaacrylate, bisphenol-A diacrylate, trimethylolpropane triacrylate, novolac epoxyacrylate, ethylene glycol dimethacrylate, diethylene glycol dimethacrylate, triethylene glycol dimethacrylate, propylene glycol dimethacrylate, 1,4-butanediol dimethacrylate, 1,6-hexanediol dimethacrylate, and the like, and combinations thereof.

The photosensitive resin composition may include the photopolymerizable monomer in an amount of about 0.5 to about 20 wt %, for example about 1 to about 10 wt %, based on the total amount (100 wt %) of photosensitive resin composition for a color filter. In some embodiments, the photosensitive resin composition may include the photopolymerizable monomer in an amount of about 0.5, 0.6, 0.7, 0.8, 0.9, 1, 2, 3, 4, 5, 6, 7, 8, 9, 10, 11, 12, 13, 14, 15, 16, 17, 18, 19, or 20 wt %. Further, according to some embodiments of the present invention, the amount of the photopolymerizable monomer can be in a range from about any of the foregoing amounts to about any other of the foregoing amounts.

When the photopolymerizable monomer is included in an amount within the above range, for example, the corner of a pattern can be clearly formed during manufacturing a color filter, so that the pattern characteristics can be enhanced and the developability to alkali development solution can be enhanced.

(E) Solvent

Examples of the solvent may include without limitation alcohols such as methanol, ethanol, and the like; ethers such as dichloroethyl ether, n-butyl ether, diisoamyl ether, methylphenyl ether, tetrahydrofuran, and the like; glycol ethers such as ethylene glycol methylether, ethylene glycol ethylether, propylene glycol methylether, and the like; cellosolve acetates such as methyl cellosolve acetate, ethyl cellosolve acetate, diethyl cellosolve acetate, and the like; carbitols such as methylethyl carbitol, diethyl carbitol, diethylene glycol monomethylether, diethylene glycol monoethylether, diethylene glycol dimethylether, diethylene glycol methylethylether, diethylene glycol diethylether, and the like; propylene glycol alkylether acetates such as propylene glycol methylether acetate, propylene glycol propylether acetate, and the like;

aromatic hydrocarbons such as toluene, xylene, and the like; ketones such as methylethylketone, cyclohexanone, 4-hydroxy-4-methyl-2-pentanone, methyl-n-propylketone, methyl-n-butylketone, methyl-n-amylketone, 2-heptanone, and the like; saturated aliphatic monocarboxylic acid alkyl esters such as ethyl acetate, n-butyl acetate, isobutyl acetate, and the like; alkyl lactate esters such as methyl lactate, ethyl lactate, and the like; alkyl hydroxyacetate esters such as methyl hydroxyacetate, ethyl hydroxyacetate, butyl hydroxyacetate, and the like; alkoxyalkyl acetate esters such as methoxymethyl acetate, methoxyethyl acetate, methoxybutyl acetate, ethoxymethyl acetate, ethoxyethyl acetate, and the like; alkyl 3-hydroxypropionate esters such as methyl 3-hydroxypropionate, ethyl 3-hydroxypropionate, and the like; alkyl 3-alkoxypropionate esters such as methyl 3-methoxypropionate, ethyl 3-methoxypropionate, ethyl 3-ethoxypropionate, methyl 3-ethoxypropionate, and the like; alkyl 2-hydroxypropionate esters such as methyl 2-hydroxypropionate, ethyl 2-hydroxypropionate, propyl 2-hydroxypropionate, and the like; alkyl 2-alkoxypropionate esters such as methyl 2-methoxypropionate, ethyl 2-methoxypropionate, ethyl 2-ethoxypropionate, methyl 2-ethoxypropionate, and the like; alkyl 2-hydroxy-2-methylpropionate esters such as methyl 2-hydroxy-2-methylpropionate, ethyl 2-hydroxy-2-methylpropionate, and the like; alkyl 2-alkoxy-2-methyl propionate esters such as methyl 2-methoxy-2-methylpropionate, ethyl 2-ethoxy-2-methylpropionate, and the like; esters such as 2-hydroxyethyl propionate, 2-hydroxy-2-methylethyl propionate, hydroxyethyl acetate, methyl 2-hydroxy-3-methylbutanoate, and the like; ketonic acid esters such as ethyl pyruvate; and the like, and combinations thereof. Further examples of the solvent may include without limitation N-methylformamide, N,N-dimethylformamide, N-methylformanilide, N-methylacetamide, N,N-dimethylacetamide, N-methylpyrrolidone, dimethylsulfoxide, benzylethylether, dihexylether, acetyl acetone, isophorone, caproic acid, caprylic acid, 1-octanol, 1-nonanol, benzylalcohol, benzyl acetate, ethyl benzoate, diethyl oxalate, diethyl maleate, γ-butyrolactone, ethylene carbonate, propylene carbonate, phenyl cellosolve acetate, and the like. These solvents may be used singularly or as a mixture of two or more.

The solvent, considering miscibility, reactivity, and the like, may include glycol ethers such as ethylene glycol monoethyl ether and the like; ethylene glycol alkylether acetates such as ethyl cellosolve acetate and the like; esters such as 2-hydroxy ethyl propionate and the like; diethylene glycols such as diethylene glycol monomethyl ether and the like; propylene glycol alkylether acetates such as propylene glycol monomethylether acetate, propylene glycol propylether acetate, and the like, and combinations thereof.

The photosensitive resin composition may include the solvent in a balance amount, for example, in an amount ranging from about 20 to about 90 wt % based on the total amount (100 wt %) of the photosensitive resin composition for a color filter. In some embodiments, the photosensitive resin composition may include the solvent in an amount of about 20, 21, 22, 23, 24, 25, 26, 27, 28, 29, 30, 31, 32, 33, 34, 35, 36, 37, 38, 39, 40, 41, 42, 43, 44, 45, 46, 47, 48, 49, 50, 51, 52, 53, 54, 55, 56, 55, 58, 59, 60, 61, 62, 63, 64, 65, 66, 67, 68, 69, 70, 71, 72, 73, 74, 75, 76, 77, 78, 79, 80, 81, 82, 83, 84, 85, 86, 87, 88, 89, or 90 wt %. Further, according to some embodiments of the present invention, the amount of the solvent can be in a range from about any of the foregoing amounts to about any other of the foregoing amounts.

When the solvent is included in an amount within the above range, the photosensitive resin composition for a color filter may have excellent coating properties and maintain improved flatness in a layer having a thickness of greater than or equal to about 2 μm.

(F) Other Additive(s)

The photosensitive resin composition for a color filter may further include one or more other additives. Examples of the additives may include without limitation malonic acid; 3-amino-1,2-propanediol; silane-based coupling agents including a vinyl group or a (meth)acryloxy group; leveling agents; fluorine-based surfactants; radical polymerization initiators, and the like, and combinations thereof, in order to prevent stains or spots during the coating, to adjust leveling, and/or to prevent pattern residues due to non-development. The fluorine-based surfactant may have a low weight average molecular weight of about 4,000 to about 10,000 g/mol, for example about 6,000 to about 10,000 g/mol. In addition, the fluorine-based surfactant may have a surface tension of about 18 to 23 mN/m (measured in 0.1% polyethyleneglycol methylether acrylate (PEGMEA) solution). When the fluorine-based surfactant has the weight average molecular weight and the surface tension within the ranges, it can provide excellent characteristics for slit coating which is a high speed coating method since the leveling performance may be improved, and the spot characteristics can be enhanced at a high speed coating, and bubbles are less likely to be formed, which can decrease film defects.

Examples of the fluorine-based surfactant may include F-482, F-484, F-478, and the like, and combinations thereof made by DIC Co., Ltd., but are not limited thereto.

The fluorine-based surfactant may be used with a silicone-based surfactant.

Examples of the silicone-based surfactant may include TSF400, TSF401, TSF410, TSF4440, and the like, and combinations thereof made by Toshiba silicone Co., Ltd., but are not limited thereto.

In addition, the photosensitive resin composition for a color filter may further include an epoxy compound to improve the close contacting (adhesive) property and other characteristics if needed.

Examples of the epoxy compound may include without limitation epoxy novolac acrylic carboxylate resins, ortho cresol novolac epoxy resins, phenol novolac epoxy resins, tetramethyl biphenyl epoxy resins, bisphenol A epoxy resins, alicyclic epoxy resins, and the like, and combinations thereof.

When further including the epoxy compound, a radical polymerization initiator such as a peroxide initiator and/or an azobis-based initiator may be further included.

The epoxy compound may be included in an amount of about 0.01 to about 5 parts by weight based on about 100 parts by weight of the photosensitive resin composition for a color filter.

When the epoxy compound is included in an amount within the above range, the storage property, the contacting adhesive property and other characteristics may be improved economically.

The method of preparing of the photosensitive resin composition for a color filter is not specifically limited. As a non-limiting example, the photosensitive resin composition for a color filter may be prepared by mixing the colorant, acrylic-based binder resin, photopolymerization initiator, photopolymerizable monomer, solvent, and optionally additive(s).

According to another embodiment of the present invention, provided is a color filter manufactured using the photosensitive resin composition for a color filter.

This color filter may be manufactured using any general conventional method. In exemplary embodiments, the color filter may be manufactured by coating the photosensitive resin composition for a color filter onto a substrate using spin-coating, roller-coating, slit-coating, and the like to form a layer have a thickness ranging from about 2 to about 4 μm. After the coating step, the layer can be radiated with a UV ray, an electron beam, or an X-ray to form a pattern required for a color filter. The UV ray may have a wavelength region ranging from about 190 to about 450 nm, for example, from about 200 to about 400 nm. Then, when the coated layer is treated with an alkali developing solution, the unradiated region thereof may be dissolved, forming a pattern for an image color filter. This process is repeated depending on the necessary number of R, G, and B colors, thereby manufacturing a color filter having a desired pattern. In addition, the image pattern acquired by the development can be cured using heat treatment, actinic ray radiation, or the like, to improve crack resistance, solvent resistance, and the like.

The photosensitive resin composition for a color filter is measured using the obtained color filter pattern, and the contrast ratio thereof may be greater than or equal to about 9000. The contrast ratio is determined by measuring light intensity when the polarizing plate is open and closed using a Contrast tester CT-1 manufactured by Tsubosaka and calculating it according to the following Equation 1.

Contrast ratio=Lₒₚₑₙ/L_{close} [Equation 1]

Lₒₚₑₙ: light intensity when the polarizing plate is open.

L_{close}: light intensity when the polarizing plate is closed.

Hereinafter, the present invention is illustrated in more detail with reference to examples. These examples, however, are not in any sense to be interpreted as limiting the scope of the invention.

### (Preparation of Pigment Dispersion)

### PREPARATION EXAMPLE 1

15 g of C.I. yellow pigment 138, 4 g of DISPERBYK-163 (manufactured by BYK), 3 g of acrylic acid/benzylmethacrylate copolymer (Miwon Commercial Co., Ltd, NPR8000), and 78 g of propyleneglycol methyletheracetate are mixed in a reactor and dispersed using a paint-shaker (manufactured by Asada) for 12 hours to provide a pigment dispersion.

### PREPARATION EXAMPLE 2

15 g of C.I. green pigment 58, 4 g of DISPERBYK-163 (manufactured by BYK), 3 g of acrylic acid/benzylmethacrylate copolymer (manufactured by

Miwon Commercial Co., Ltd, NPR8000), and 78 g of propyleneglycol methyletheracetate are mixed in a reactor and dispersed using a paint-shaker (manufactured by Asada) for 12 hours to provide a pigment dispersion. (Preparation of Photosensitive Resin Composition for Color Filter) Components used for preparing photosensitive resin compositions are as follows.

(A) Colorant

(A-1) Color Material Having Transmittance of About 0 to About 40% in a Wavelength Region of About 490 to About 500 nm, and Transmittance of About 70 to About 100% in a Wavelength Region of About 520 to About 530 nm

(A-1-1) MACROLEX Yellow 6G (manufactured by Lanxess) is used.

(A-1-2) Yellow 2R (manufactured by Kyung-In Synthetic Corporation) is used.

(A-1-3) the pigment dispersion obtained from Preparation Example 1 is used. In this case, the pigment solid content is included in an amount of 22% based on the total amount of the pigment dispersion.

(A-2) Green Pigment

The pigment dispersion obtained from Preparation Example 2 is used. In this case, the pigment solid is included in an amount of 23% based on the total amount of the pigment dispersion.

(B) Acrylic-Based Binder Resin

The methacrylic acid/benzylmethacrylate copolymer (mixing weight ratio 30/70) having a weight average molecular weight of 28,000 g/mol is used.

(C) Photopolymerizable Monomer

Dipentaerythritolhexaacrylate is used.

(D) Photopolymerization Initiator

CGI-124 (oxime-based photopolymerization initiator) is used.

(E) Solvent

Propyleneglycol monomethyletheracetate is used.

(F) Additive

A fluorine-based surfactant (F-554, DIC Co., Ltd) is used.

### EXAMPLES 1 AND 2 AND COMPARATIVE EXAMPLE 1

Each component is mixed according to amounts of the compositions shown in the following Table 1 to provide a photosensitive resin composition for a color filter. Specifically, a photopolymerization initiator is dissolved in a solvent and agitated at a room temperature for 2 hours and then an acrylic-based binder resin and a photopolymerizable monomer are added and agitated at a room temperature for 2 hours. Subsequently, a colorant is added and agitated at a room temperature for 2 hours, and then a surfactant is added and agitated at a room temperature for 1 hour. The solution is filtered two times to remove impurities to provide a photosensitive resin composition for a color filter.

TABLE 1
(wt %)

| | | | | | Comparative |
|---|---|---|---|---|---|
| | | | Examples | | Example |
| | | | 1 | 2 | 1 |
| (A) Colorant | (A-1) Color material | (A-1-1) | 2.0 | — | — |
| | | (A-1-2) | — | 2.0 | — |
| | | (A-1-3) | — | — | 6.0 |

| | | | |
|---|---|---|---|
| (A-2) Green pigment | 40 | 40 | 40 |

| | | | |
|---|---|---|---|
| (B) Acrylic-based binder resin | 4.0 | 4.0 | 4.0 |
| (C) Photopolymerizable monomer | 4.0 | 4.0 | 4.0 |
| (D) Photopolymerization initiator | 2.0 | 2.0 | 2.0 |
| (E) Solvent | 47.98 | 47.98 | 43.98 |
| (F) Surfactant | 0.02 | 0.02 | 0.02 |

### Evaluation 1: Measurement of Spectral Characteristics of Color Material

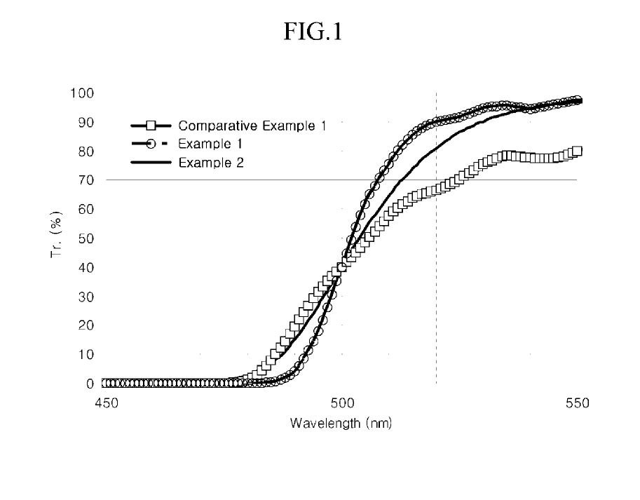

(A-1) Individual ones of the color materials according to Examples 1 and 2 and Comparative Example 1 or a mixed material with (B) a binder resin and (E) a solvent is coated on a defatted cleaned glass substrate having a thickness of 0.65 mm to provide a transmittance of 50% based on 500 nm and dried on a hot plate at 90° C. for 2 minutes to provide a coating. The obtained specimen is measured for a spectral characteristic using a spectrophotometer (MCPD3000, manufactured by Otsuka electronic). The results are shown in the following Table 2 and FIG. 1.

TABLE 2

| | Transmittance | Transmittance |
|---|---|---|
| | (@500 nm reference) | (@530 nm reference) |
| Example 1 | 40% | 95% |
| Example 2 | 40% | 90% |
| Comparative Example 1 | 40% | 75% |

Referring to Table 2, it is understood that the color material according to Example 1 has a transmittance of 40% at 500 nm and a transmittance of 95% at 530 nm; the color material according to Example 2 has a transmittance of 40% at 500 nm and a transmittance of 90% at 530 nm; and the color material according to Comparative Example 1 has a transmittance of 40% at 500 nm and a transmittance of 75% at 530 nm.

### Evaluation 2: Measurement of Spectral Characteristics of Photosensitive Resin Composition for a Color Filter

On a defatted cleaned glass substrate having a thickness of 0.65 mm, a photosensitive resin composition for a color filter is coated to a thickness of 2 to 4.5 μm and dried on a hot plate of 90° C. for 2 minutes to provide a coating. Subsequently, the coating is exposed using a high-pressure mercury lamp having a wavelength of 365 nm and then dried for 20 minutes in a hot-air drying furnace at 160° C. to provide a specimen. The obtained specimen is measured for a spectral characteristic using a spectrophotometer (MCPD3000, manufactured by Otsuka electronic), and the results are shown in the following Table 3.

TABLE 3

| Color coordinate | | Transmittance |
|---|---|---|
| (x, y) = (0.300, 0.650) | Luminance (Y) | (@540 nm reference) |
| Example 1 | 41 | 80% |
| Example 2 | 50 | 80% |
| Comparative Example 1 | 38 | 60% |

Referring to the Table 3, it is understood that Examples 1 and 2 including the colorant according to one embodiment have higher luminance and higher transmittance at a predetermined wavelength region, for example, 540 nm compared to Comparative Example 1.

Many modifications and other embodiments of the invention will come to mind to one skilled in the art to which this invention pertains having the benefit of the teachings presented in the foregoing descriptions. Therefore, it is to be understood that the invention is not to be limited to the specific embodiments disclosed and that modifications and other embodiments are intended to be included within the scope of the appended claims. Although specific terms are employed herein, they are used in a generic and descriptive sense only and not for purposes of limitation, the scope of the invention being defined in the claims.

What is claimed is:

1. A photosensitive resin composition for a color filter, comprising (A) a colorant including green pigment and a color material having transmittance of about 0 to about 40% in a wavelength region of about 490 to about 500 nm and transmittance of about 70 to about 100% in a wavelength region of about 520 to about 530 nm;
(B) an acrylic-based binder resin;
(C) a photopolymerization initiator;
(D) a photopolymerizable monomer; and
(E) a solvent.

2. The photosensitive resin composition for a color filter of claim 1, wherein the color material has transmittance of about 80 to about 100% in a wavelength region of about 520 to about 530 nm.

3. The photosensitive resin composition for a color filter of claim 1, wherein the color material comprises C.I. solvent yellow 19, C.I. solvent yellow 21, C.I. solvent yellow 179, C.I. yellow pigment 150, C.I. yellow pigment 185, or a combination thereof.

4. The photosensitive resin composition for a color filter of claim 1, wherein the green pigment comprises C.I. green pigment 7, C.I. green pigment 36, C.I. green pigment 58, or a combination thereof.

5. The photosensitive resin composition for a color filter of claim 1, wherein the colorant comprises the color material and the green pigment in a weight ratio of about 20:1 to about 1:20.

6. The photosensitive resin composition for a color filter of claim 1, wherein the photosensitive resin composition for a color filter comprises:
about 0.01 to about 60 wt % of the colorant (A),
about 0.5 to about 20 wt % of the acrylic-based binder resin (B),
about 0.1 to about 10 wt % of the photopolymerization initiator (C),
about 0.5 to about 20 wt % of the photopolymerizable monomer (D), and
a balance amount of the solvent (E).

7. A color filter manufactured using the photosensitive resin composition for a color filter of claim 1.
